(19) United States
(12) Patent Application Publication
(10) Pub. No.: US 2009/0278530 A1
(43) Pub. Date: Nov. 12, 2009

(54) SENSOR SYSTEM

(76) Inventors: Wolfgang Welsch, Heidelberg (DE); Matthias Moerbe, Schwieberdingen (DE); Christian Bauer, Schwieberdingen (DE)

Correspondence Address: MICHAEL J. STRIKER, 103 EAST NECK ROAD, HUNTINGTON, NY, 11743, US

(21) Appl. No.: 11/915,832

(22) PCT Filed: Jul. 17, 2006
(86) PCT No.: PCT/EP2006/064318

§ 371 Date: Nov. 28, 2007

(30) Foreign Application Priority Data
Aug. 25, 2005 (DE) 102005040168.6

(51) Int. Cl. G01R 33/07; G01B 7/00

(52) U.S. Cl. 324/207.2; 324/207.11

(57) ABSTRACT

Disclosed is a sensor array for evaluating the signals of a magnetically sensitive sensor, in which the changes in the magnetic field caused by a moved transmitting element (10) are evaluated by forming the difference. The transmitting element (10) is fitted with a plurality of magnetic poles (14, 16). A soft magnetic collecting element (18, 20) is provided which taps the magnetic field of at least two magnetic poles (14, 16) of the same kind and feeds said magnetic field to the sensor element (22).

### RELATED ART

The present invention is directed to a sensor array according to the general class of the independent claim. Publication DE 10357147 A1 makes known a magnetic sensor array for evaluating the signals from a magnetically sensitive sensor element, with which the magnetic field changes caused by a moved transmitting element and the resultant switching edges may be evaluated. When the transmitting element equipped with the permanent magnet moves past the stationary sensor element, an output signal for producing the switching edges is generated. A field amplifier is provided, preferably a soft-magnetic element, which is located on the side behind the sensor element facing away from the transmitting element, in order to increase the measurement sensitivity at the measurement site by focusing the field.

Publication EP 1424541 A2 makes known a device for determining a torque that is exerted on a shaft, the shaft including a first shaft section and a second shaft section, and the two shaft sections being rotatable relative to each other. A multiple-pole magnetic ring encloses the first shaft section and is connected therewith. A stator holder is mounted on a second shaft section. Two stator elements are installed on the stator holder, and each stator element includes fingers that extend in the axial direction, the fingers being assigned to the gaps between the poles of the magnetic ring. With this system, a differential signal of the detected magnetic field is not calculated, however. While publication EP 1424541 A2 is directed to the determination of a torque (small angle measurement), the present invention is directed to the detection of motion (incremental measurement). The field of application is therefore fundamentally different.

The object of the present invention is to improve the signal evaluation. This object is achieved by the features of the independent claim.

### ADVANTAGES OF THE INVENTION

The inventive sensor array having the features of the independent claim has the advantage that the soft-magnetic collector element, which taps the magnetic field of at least two similarly magnetized poles and supplies them to the sensor element, permits the geometry of the transmitting element to be decoupled from the geometry of the sensor element. The soft-magnetic collector elements collect the magnetic flux of the particular north pole or south pole—which is preferably located on a multiple-pole ring—and direct it, at this point, to the sensor element, which is designed to calculate differences, so that the two magnetically sensitive cells of the sensor element always experience magnetic flux density signals that are phase-shifted by 180°. The phase position is therefore independent of the particular pole length of the multiple-pole transmitting element, since the adjustment takes place via the soft-magnetic collector elements. Using a single differential sensor element (e.g., a differential Hall IC) with a fixed separation between sensor cells, highly diverse pole pitches may therefore be covered. An additional advantage is the fact that the incremental error (i.e., the deviation of the real switching points of the sensor element from the ideal value of the multiple-pole sensor) is reduced by averaging the magnetic flux density of several poles.

In an advantageous refinement it is provided that the collector elements are designed with a comb structure. The distances between the comb extensions may be tailored to the particular transmitting element. The same sensor element with a fixed cell separation between the two magnetically sensitive cells may therefore always be used for a different number of multiple-pole pairs and for different reading radii on the multiple-pole wheel. The phase position of the magnetic flux density signals on the two magnetically sensitive cells may always be set at 180° (optimum). The maximum possible differential signal of the two magnetically sensitive cells is therefore attained in every case. The large number of comb extensions produces a collective effect, which results in signal amplification. Collecting the magnetic flux from several poles also results in an averaging effect, thereby reducing the incremental error. Via this averaging, magnetic field inhomogeneities and differences in pole lengths may be compensated for. As a result, the individual incremental error and cumulative incremental error (a sign-exact summing of individual incremental errors at a particular switching point) may be reduced.

In an advantageous refinement it is provided that a return element and/or a ferromagnetic structure of the sensor element is provided to minimize the air gap between the tapping structure and the return. The signal evaluation is further improved as a result.

Further advantageous refinements result from the further dependent claims and the description.

### DRAWING

An exemplary embodiment of the inventive sensor array is depicted in the drawing and is described in greater detail below.

FIG. 1 shows a model of an axially magnetized multiple-pole wheel with a north pole, a south pole, an inner ring, and soft-magnetic pick-ups, which are designed as semicircles,

FIG. 2 shows a section of the system in FIG. 1 with a more detailed depiction of the design of the sensor element with return element, and

FIG. 3 shows the angle-dependent signal graph of the magnetic flux density B detected by the two magnetically sensitive cells, and the differential signal derived therefrom.

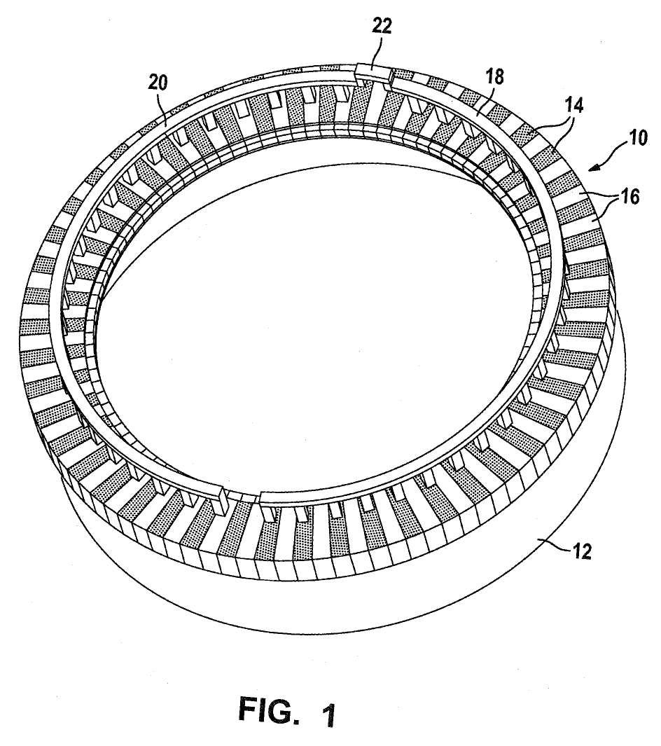

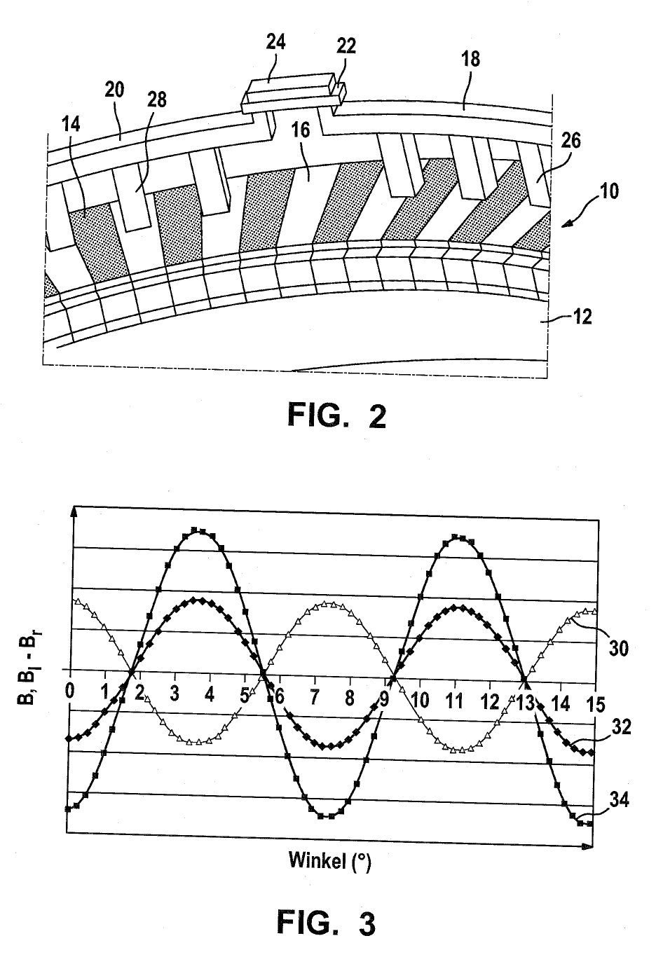

### DETAILED DESCRIPTION OF THE EXEMPLARY EMBODIMENT

A transmitting element 10 is composed of a ring 12, which includes alternating north poles 14 and south poles 16 as an axially magnetized multiple-pole wheel. Ring 12 is designed as a metallic carrier ring, on which the separate multiple-poled ring is installed. A first semicircular collector element 18 is located at an axial distance away from north poles 14 and south poles 16, and is equipped with first comb extensions 26, which extend in the axial direction away from the ring structure in the direction toward magnetic poles 14, 16. A second collector element 20 is also provided, which is also equipped with corresponding second comb extensions 28, which are also located at an axial distance, as is the case with first collector element 18. The geometry of the first and second comb extensions 26, 28 is selected such that it is matched to the geometry of magnetic poles 14, 16 of transmitting element 10 in the circumferential direction. First comb extensions 26 and second comb extensions 28 are displaced relative to each other such that, when poles 14, 16 are oriented in the center over comb extensions 26, 28, first comb extensions 26 tap, e.g., the magnetic field of north pole 14, while second comb extensions 28 tap the magnetic field of south pole 16 in this position. Collector elements 18, 20 are fixed in position relative to moving transmitting element 10. The magnetic field tapped by collector elements 18, 20 is supplied via extensions formed on the end of the segments of collector elements 18, 20 to a sensor element 22, which is therefore located between collector elements 18, 20. A return element 24 is located on the side of sensor element 22 facing away from collector element 18, 20; it guides the magnetic field lines to the opposite pole. Sensor element 22 includes two magnetically sensitive cells, which are referred to here as the left and right magnetically sensitive cells. The left magnetically sensitive cell detects magnetic flux density B supplied by second collector element 20, which changes in a sinusoidal manner as a function of the angle (transmitting element 10 rotates relative to sensor element 22). First collector element 18 directs tapped magnetic flux density B to the right magnetically sensitive cell. Magnetic flux density B has the sinusoidal shape labeled with reference numeral 30. Output signal 30 of the right magnetically sensitive cell is phase-shifted by 180° relative to output signal 32 of the left magnetically sensitive cell. A differential signal 34 is calculated from the two output signals 30, 32 by calculating the difference. Differential signal 34 has the sinusoidal shape shown in FIG. 3 with twice the amplitude of output signals 30, 32. Disturbing external fields may be suppressed by calculating the difference.

The magnetic sensor array shown is used, e.g., to detect displacement, rotational speed, or position, as is used, e.g., to control engines or for measurement purposes in transmission or driving dynamics controls in motor vehicles. The motion of ferromagnetic transmitting element 10 is detected by a stationary sensor element 22 located opposite to transmitting element 10. Magnetically sensitive sensor element 22 may be designed as a Hall sensor, or it may be based on another magnetic field sensor technology, such as AMR, GMR or TMR. First and second collector elements 18, 20 are composed of two half-rings with a comb-like structure, composed of first comb extensions 26 and second comb extensions 28 made of soft-magnetic material, which collect the magnetic flux of a pole type (north pole 14, south pole 16) and direct them in the direction of sensor element 22. The distances between comb extensions 26, 28 may be tailored to particular sensor element 10. A multiple-pole wheel may be used, e.g., as transmitting element 10. Instead of detecting a rotational motion, the principle described may be used to detect linear motion. First comb extensions 26 and second comb extensions 28 are preferably offset by the length of one pole of transmitting element 10. As a result, only the magnetic flux of one pole type is collected by one collector element 18,20.

Sensor element 22 is composed, e.g., of a right magnetically sensitive cell and a left magnetically sensitive cell, as could be the case with a Hall sensor, for example. Its magnetically sensitive cells detect only one certain magnetic field direction. For example, one magnetically sensitive cell could detect the magnetic field component that is oriented perpendicularly from transmitting element 10 to sensor element 22, while the other magnetically sensitive cell detects the component of the magnetic field that is oriented from above in the direction of transmitting element 10. The right magnetically sensitive cell detects the supplied component of magnetic flux density B, which is oriented in the direction of the right magnetically sensitive cell. The left magnetically sensitive cell detects the supplied component of magnetic flux density B, which is oriented in the direction of the left magnetically sensitive cell. With this geometric design, the two cells emit output signals 30, 32 that are phase-shifted by 180°. A switching circuit is integrated in sensor element 22, which calculates the difference from output signal 30 of the right magnetically sensitive cell and output signal 32 of left magnetically sensitive cell, thereby resulting in differential signal 34. As a result of the phase shift of, optimally, 180°, the amplitude of sinusoidal differential signal 34 doubles, thereby improving the evaluation. Differential signal 34 is a measure of the angle between transmitting element 10 and sensor element 22, which is fixed in position relative to transmitting element 10.

To direct the magnetic field lines to the opposite pole, and to adapt the magnetic field lines to the detection direction of the magnetically sensitive cells, a return element 24 is provided, which is located between the first and second collector element 18, 20, and preferably such that the magnetic field tapped by collector elements 18, 20 is supplied to the corresponding magnetically sensitive cells. Instead of a separate return element 24, a sensor element with a ferromagnetic lead frame could be used to minimize the air gap between the tapping structure 18, 20 and the return.

The inventive sensor array has the effect of averaging and therefore reducing the incrementing error. The incrementing error is the deviation of the real switching point of the IC relative to the ideal switching point given an ideal course of the magnetic field over a pole.

The magnetic circuit may be used in magnetic differential field sensors that are excited using multiple-pole elements. As a prerequisite, there must be access to a large portion of the multiple-pole elements, such as with a cap sensor. The sensor array provided is suited for use, in particular, in rotational speed sensors on wheels, e.g., of a motor vehicle, as a rotational speed sensor in a transmission, or with linear displacement sensors, angular sensors, or proximity sensors, with which the magnetic field changes are induced via moved magnetic pole elements.

What is claimed is:

1. A sensor array for evaluating the signals of a magnetically sensitive sensor element (22), with which the magnetic field changes caused by a transmitting element (10) are evaluated by calculating the difference, the transmitting element (10) including a large number of magnetic poles (14, 16),
wherein
at least one soft magnetic collector element (18, 20) is provided that taps the magnetic field of at least two identical magnetic poles (14, 16) of the transmitting element (10) and supplies it to the sensor element (22), the transmitting element (10) and the collector element (18, 20) being positioned such that they are movable relative to each other.

2. The sensor array as recited in claim 1,
wherein
the collector element (18, 20) is designed with a comb structure.

3. The sensor array as recited in claim 1,
wherein
a second collector element (20) is provided to tap the magnetic field of at least two identical magnetic poles (16).

4. The sensor array as recited in claim 1,
wherein
the sensor element (22) includes two magnetically sensitive cells, preferably Hall cells.

5. The sensor array as recited in claim 1,
wherein
a differential signal (34) is formed from an output signal (30) from the first magnetically sensitive cell and an output signal (32) from the second magnetically sensitive cell.

6. The sensor array as recited in claim 1,
wherein
a return element (24) is provided for closing the magnetic circuit of the oppositely-magnetized poles (14, 16).

7. The sensor array as recited in claim 1,
wherein
the transmitting element (10) is designed as multiple-pole wheel.

8. The sensor array as recited in claim 1,
wherein
the collector element (18, 20) includes comb extensions (26, 28), which are oriented in the direction toward the transmitting element (10).

9. The sensor array as recited in claim 1,
wherein
the comb extensions (26, 28) are matched to the geometric structure of the transmitting element (10).
